(19) United States
(12) Patent Application Publication
(10) Pub. No.: US 2020/0307145 A1
(43) Pub. Date: Oct. 1, 2020

(54) FUNCTIONAL COMPOSITE ENCLOSURE FOR AN ELECTRONIC DEVICE

(71) Applicant: Apple Inc., Cupertino, CA (US)

(72) Inventors: Daniel B. Sargent, San Francisco, CA (US); Andrea L. Blakemore, San Francisco, CA (US); John Raff, Menlo Park, CA (US)

(21) Appl. No.: 16/523,767

(22) Filed: Jul. 26, 2019

Related U.S. Application Data
(60) Provisional application No. 62/827,647, filed on Apr. 1, 2019.

(51) Int. Cl. B32B 5/02; B32B 7/12; B32B 15/04; B32B 15/18; B32B 15/20; B32B 3/04; H05K 5/00; B32B 3/26

(52) U.S. Cl. CPC B32B 5/02; B32B 2457/20; B32B 15/04; B32B 15/18; B32B 15/20; B32B 3/04; H05K 5/0017; B32B 3/266; B32B 2255/06; B32B 2262/101; B32B 2262/106; B32B 2262/14; B32B 2255/02; B32B 2307/554; B32B 7/12

(57) ABSTRACT

A housing for an electronic device at least partially defines an interior volume of the electronic device and retains a display. The housing can also include a backplate, including an exterior layer at least partially defining an exterior surface of the housing, a first structural layer bonded to the exterior layer, a functional component directly bonded to the first layer, and a second structural layer overlying the functional component.

### CROSS-REFERENCE TO RELATED APPLICATION(S)

This claims priority to U.S. Provisional Patent Application No. 62/827,647, filed 1 Apr. 2019, and entitled “FUNCTIONAL COMPOSITE ENCLOSURE FOR AN ELECTRONIC DEVICE,” the entire disclosure of which is hereby incorporated by reference.

### FIELD

The described embodiments relate generally to electronic devices. More particularly, the present embodiments relate to enclosures for electronic devices.

### BACKGROUND

Electronic devices are widespread in society and can take a variety of forms, from wristwatches to computers. There is a strong demand for electronic devices, especially portable electronic devices such as handheld phones, tablet computers, and watches, to be thin and lightweight while simultaneously including numerous features and delivering high performance.

Certain components of electronic devices, such as enclosures or housings, typically perform a structural function and provide for device durability, as well as resistance to any mechanical or thermal stresses experienced by the device. Such components, however, may need to be a certain size or thickness in order to achieve a desired level of performance. This required thickness either reduces the available internal volume in which to house components, or adds to the overall thickness and/or weight of the electronic device.

### SUMMARY

According to some aspects of the present disclosure, an electronic device includes a display and a housing at least partially defining an interior volume of the electronic device and configured to retain the display. The housing can include a backplate having an exterior layer at least partially defining an exterior surface of the housing, a first structural layer bonded to the exterior layer, a functional component directly bonded to the first structural layer, and a second structural layer overlying the functional component.

In some examples, the backplate can further include a core layer at least partially surrounding the functional component, the core layer being disposed between and bonded to both the first structural layer and the second structural layer. The exterior layer can include at least one of a physical vapor deposited layer, a metal layer, a ceramic layer, a glass layer, an in-mold coated layer, an ink layer, or a paint layer. The first structural layer and the second structural layer can include fiberglass, carbon fiber, or a carbon fiber and fiber glass hybrid. The core layer can include fiberglass, carbon fiber, or a carbon fiber and fiber glass hybrid. The functional component can be less than about 0.2 mm from the portion of the exterior surface defined by the exterior layer. The functional component can include one or more of a magnet, an antenna, a via, a cable, a battery, or a thermal spreader.

According to some aspects, a housing of an electronic device can include a support layer including or defining an aperture, an exterior layer bonded to the support layer that occludes the aperture. The exterior layer can at least partially define an exterior surface of the electronic device, and a functional component can be bonded directly to the exterior layer through the aperture.

In some examples, the housing can further include an interior layer overlying the functional component and the support layer, the interior layer being bonded to the support layer. The support layer can at least partially define an internal volume of the electronic device, and at least a portion of the functional component is disposed within the interior volume. The functional component can include one or more of a magnet, an antenna, a via, a cable, a battery, electrical components, or a thermal spreader. The exterior layer can include at least one of a physical vapor deposited layer, a metal layer, a ceramic layer, a glass layer, an in-mold coated layer, an ink layer, or a paint layer. The exterior layer can have a thickness of less than about 0.2 mm. The support layer can include one or more of fiberglass, carbon fiber, a carbon fiber and fiber glass hybrid, or steel. The housing can further include an adhesive layer bonding the functional component to the exterior layer. The housing can further include one or more additional functional components, wherein the support layer further includes or defines one or more additional apertures and the one or more additional functional components are bonded directly to the exterior layer through the one or more additional apertures.

According to some aspects, a housing of an electronic device can include a core layer at least partially surrounding one or more functional components, a structural layer bonded to the core layer and at least partially covering the one or more functional components, and an exterior layer bonded to the structural layer and defining an exterior surface of the electronic device.

In some examples, the functional component can be disposed less than about 0.2 mm from the exterior surface defined by the exterior layer. The structural layer can include at least one of steel, titanium, aluminum, or other metals. The housing can further include an interior structural layer bonded to a surface of the core layer opposite the structural layer, wherein the structural layer, the core layer, and the interior structural layer cooperate to substantially surround the functional component.

### BRIEF DESCRIPTION OF THE DRAWINGS

The disclosure will be readily understood by the following detailed description in conjunction with the accompanying drawings, wherein like reference numerals designate like structural elements, and in which:

FIG. 1A shows a front perspective view of an electronic device.

FIG. 1B shows a rear perspective view of an electronic device.

FIG. 2 shows an exploded perspective view of an electronic device.

FIG. 3A shows a front perspective view of an electronic device.

FIG. 3B shows a schematic cross-sectional view of an electronic device.

FIG. 4A shows a front perspective view of an electronic device.

FIG. 4B shows a cross-sectional view of an electronic device.

FIG. 5A shows a front perspective view of an electronic device.

FIG. 5B shows a cross-sectional view of an electronic device.

FIG. 6A shows a front perspective view of an electronic device.

FIG. 6B shows a top cutaway view of a portion of a housing of an electronic device.

FIG. 7 shows a side cross-sectional view of a portion of a housing of an electronic device.

FIG. 8 shows a side cross-sectional view of a portion of a housing of an electronic device.

FIG. 9 shows a side cross-sectional view of a portion of a housing of an electronic device.

FIG. 10 shows a side cross-sectional view of a portion of a housing of an electronic device.

FIG. 11 shows a side cross-sectional view of a portion of a housing of an electronic device.

### DETAILED DESCRIPTION

The present description provides examples, and is not limiting of the scope, applicability, or configuration set forth in the claims. Thus, it will be understood that changes can be made in the function and arrangement of elements discussed, without departing from the spirit and scope of the disclosure, and various embodiments can omit, substitute, or add other procedures or components, as appropriate. For instance, methods described can be performed in an order different from that described, and various steps can be added, omitted, or combined. Also, features described with respect to some embodiments can be combined in other embodiments.

One aspect of the present disclosure relates to composite enclosures or housings for electronic devices. In some examples, a housing for an electronic device defines an internal volume of the device and includes a portion, such as cover or backplate, that defines an exterior surface, such as a major surface opposite the display of the electronic device. The backplate includes an exterior layer that at least partially defines the exterior surface of the housing. The exterior layer can be an exterior coating, such as a ceramic coating, paint coating, physical vapor deposited (PVD) coating, glass, or another appropriate and desirable exterior coating. The exterior layer can be a decorative exterior layer. This exterior layer provides a pleasing cosmetic appearance to a user and can exhibit a desired level of hardness and durability. The backplate includes a first structural layer bonded to the exterior layer. The structural layer provides rigidity and mechanical strength to the exterior layer and enclosure with a material that does not have the same hardness, durability, or cosmetic requirements as the exterior layer, thereby resulting in lower costs, greater ease of manufacturing, lower weight, and other design benefits.

The backplate also includes a core or support layer bonded to the first structural layer. This core layer supports the structural layers of the backplate and can be a lightweight and low cost material, such as fiberglass, foam, or glue. Further, a functional component can be incorporated into the core layer, or can be all or part of the core layer itself. Examples of functional components that can be included in the composite backplate include magnets, cables, vias, batteries, electrical traces, ground planes, power rails, thermal components such as thermal spreaders, inductive charging components, and other similar functional components. A second structural layer can overlie and be bonded to the core layer and/or functional component. This second structural layer can include the same material as the first structural layer, again providing desired mechanical properties to the composite backplate. Accordingly, the composite backplate construction described herein can provide an electronic device with an exterior surface having a desired hardness, durability, and appearance, while, for example, being relatively low cost, thin, and lightweight. Further, the inclusion of functional components in the backplate allows the backplate to provide the electronic device with additional functionality that is not merely structural, thereby maximizing the useful internal space of the device.

Typically, electronic device enclosures or housings are primarily formed of a material that serves to define the exterior surface of the device while also providing a level of mechanical support and strength to withstand typical device use. In such examples, portions of the device enclosure, for example a backplate or back cover, are formed with a certain thickness in order to impart the desired mechanical, durability, and hardness properties to the enclosure. The thickness of the enclosure, including the backplate of the enclosure, contributes to, and often defines, the overall thickness of the electronic device without providing any functionality beyond the structural features discussed. Further, because traditional back covers are typically formed primarily from a monolithic material, achieving a desired surface finish or appearance often requires processes that can compromise the mechanical durability and hardness of the material.

Accordingly, the functional composite enclosures described herein can provide or include a functional component or components as part of the enclosure, while also including a composite construction that allows for the optimization of desired exterior properties and overall mechanical properties without unnecessarily adding to the overall dimensions of the enclosure. The inclusion of a functional component or components in or on portions of the device enclosure, such as the backplate, further serves to add functionality to what has traditionally been a purely structural component of the device. This functionality can allow for additional utilization of the available internal space of the electronic device, resulting in thinner devices and/or the ability to include additional or larger components in a traditional sized device.

Additionally, the inclusion of one or more functional components in the composite device enclosure, for example magnets, cables, vias, batteries, thermal components such as thermal spreaders, inductive charging components, and other functional components, can allow for these components to be positioned close to the exterior surface of the device, and in some examples, closer than can be achieved with traditional enclosure construction. The increased proximity of the functional components of the composite enclosure to the exterior environment can improve component efficiency. For example, in some examples where a composite enclosure includes inductive charging components, the present construction can improve the efficiency of the inductive charging. In some examples, where a composite enclosure includes a magnetic functional component, the performance requirements of the functional component can be reduced relative to a similar component in a device with a traditional enclosure. That is, the closer proximity between a magnetic component and the exterior environment can allow for the use of components with weaker magnetic fields to achieve the same or similar results, thereby providing cost savings or additional functionality.

Positioning these functional components in the device enclosure allows for additional configurations for the other components of the device. In some examples, the inclusion of vias or relays in a composite device enclosure can allow for the arrangement of other components of the device, such as internal components, in arrangements that have traditionally been too difficult or costly to manufacture or otherwise untenable or impractical.

In addition to providing added functionality to a component relative traditional constructions, the present configuration can leverage the functional component to provide support or mechanical strength to one or more portions of the enclosure. For example, if a composite backplate includes a functional component such as a magnet, the functional component can provide mechanical support to other portions of the backplate, such as the exterior layer or the structural layer. By serving multiple purposes, functional as well as structural, the composite construction of the backplate can add functionality to an enclosure, without an increase in thickness, weight, or other parameters that might have been expected of typical device enclosures.

Additionally, a portion of a composite device enclosure, such as a backplate, can include an exterior layer or coating that can at least partially define an exterior surface of the electronic device. The exterior layer can be formed of a material that has desired hardness, durability, and cosmetic properties. For example, an exterior layer or coating can have a hardness approximately equal to or greater than the hardness of glass or aluminum. Furthermore, the exterior layer or coating can include a material that provides a desired surface finish and cosmetic appearance to the electronic device, such has by obscuring or hiding the functional components of the composite enclosure and providing a desired color or finish. In some examples, an exterior layer of a portion of a composite enclosure can include a ceramic coating, a paint coating, a physical vapor deposited (PVD) coating, glass, metal, or other desirable external materials.

As described herein, a composite enclosure, or a portion thereof such as a backplate, can include a structural layer bonded to the exterior layer or coating. The structural layer can provide rigidity and mechanical strength to the enclosure, the housing, and the entire electronic device, while utilizing a material that does not require the same hardness, durability, or cosmetic appearance as the exterior layer. This results in lower costs, greater ease of manufacturing, lower weight, and other beneficial characteristics. The structural layer can include, for example, a fiber reinforced composite material, such as a fiber reinforced polymer material, fiberglass material, carbon fiber material, fiberglass-carbon fiber hybrid material, metal, such as aluminum, steel, titanium, and other desirable structural materials.

In some examples, such as where the exterior layer is a coating, the structural layer can support the exterior layer. In some examples, the exterior layer can be formed directly on the structural layer, such as by any number of deposition methodologies, such as physical vapor deposition. In some examples, an exterior layer can be formed from a portion of the structural layer, for example by oxidizing the surface of the structural layer. In other examples, the exterior layer can be bonded to the structural layer by an adhesive, such as an epoxy or resin adhesive, brazing, welding, or any other appropriate bonding or joining materials or techniques. In some examples, two or more layers can be bonded by a layer of an adhesive, such as epoxy. In some examples, an epoxy resin with an amine hardener can be used. In some examples, an adhesive can be a substantially shear-resistant glue or epoxy, such that the adhesive layer can be substantially rigid, for example about as rigid or shear resistant as a layer of the functional composite enclosure. In some examples, however, the adhesive layer can be less rigid than a layer of the functional composite enclosure and can, for example, absorb shear energy between the joined layers. Thus, in some instances, an adhesive layer can be substantially less rigid than a layer or layers being joined by the adhesive layer, which can help with impact/shock scenarios.

In some examples, at least a portion of a composite enclosure can include a core layer, also referred to as a support layer, bonded to one or more structural layers of the composite enclosure. The core layer can be bonded to a structural layer or layers by in any suitable manner, including by adhesives such as epoxy or resin adhesives, welding, brazing, and other suitable bonding materials or processes. In some examples, the core layer can serve to support, join together, and/or position the structural layers of the composite enclosure. In some examples, the core layer can be a lightweight and low cost material, such as fiberglass, foam, or glue. In some examples, the core layer can include a fiber reinforced composite material, such as a fiber reinforced polymer composite. In some examples, the core layer can include one or more of a fiber reinforced polymer material, fiberglass material, carbon fiber material, fiberglass-carbon fiber hybrid material, metal, such as aluminum, steel, titanium, or other similarly desirable materials.

A functional composite enclosure, as described herein, can also include one or more functional components embedded or forming part of the enclosure. In some examples, a functional component can include a magnets, cables, vias, batteries, thermal components such as thermal spreaders, inductive charging components, and other desirable functional components. A functional component can include any component or portion of the enclosure that performs, or is capable of performing, a function that is not purely mechanical or cosmetic. In some examples, a functional component can include processors, memory, data storage, displays, sensors, input components, and similarly functional elements.

In some examples, the functional component can be an active functional component or a passive functional component. In some examples, a passive functional component can be any functional component that is capable of performing a function that is not purely mechanical or cosmetic, but that does not perform the function without some input, initiating operation, signal, power, or other feedback from an external source or other functional component. Examples of passive functional components include, wires, cables, vias, relays, thermal conductors, and the like. In some examples, an active functional component can be any functional component that is capable of modifying a state, characteristic, or performing a function automatically in response to an input, signal, or feedback. An active functional component can be any functional component that is not a passive functional component. Examples of active functional components include sensors, batteries, processors, memory, displays, input components, and the like. In some examples, an active functional component can include, for example, a magnet connected to a Hall effect sensor that is triggered when an accessory or other device couples with or is within a desired proximity of the magnet. In use, positioning an accessory that includes a magnet adjacent to or within a desired range of the active functional component can trigger the Hall effect sensor and automatically send a signal to one or more other functional components of the electronic device. For example, positioning an accessory or second device that includes a magnet within a desired range of the active functional component can trigger the sensor to send a signal that the accessory has been coupled to the electronic device or that a modular device has been connected to the electronic device. Examples of such accessories or second devices include input devices, such as a keyboard or stylus, covers, audio devices, display devices, electronic devices such as watches, phones, tablets, and computers.

A functional component can be embedded, incorporated, or otherwise at least partially included in the core layer of the composite enclosure. In some examples, the functional component can serve as all or only part of the core layer. A core layer can include a gap, space, recess, or aperture that is configured to receive all or a portion of a functional component. For example, a functional component can be peripherally surrounded by the core layer, such that the functional component operates in a mechanically similar manner to the surrounding core layer. Thus, the structural layer and the functional component can cooperate to mechanically support the exterior layer. In some examples, the core layer can be a non-continuous layer, and two or more otherwise discontinuous portions of core layer can be disposed substantially adjacent to one or more surfaces of a functional component.

In some examples, a functional component can be positioned in a gap, space, recess, aperture, or other feature of a core layer, after such a feature has been formed in the core layer. In some examples, the feature of the core layer can be formed by a subtractive process, such as machining or milling. In some examples, the core layer can be molded, pressed, or otherwise formed into a desired shape. In other examples, however, the core layer can be additively built up or formed around the one or more functional components. In yet other examples, any combination of additive or subtractive processes can be used to form a core layer, as described herein. In some examples, a portion of a functional component passing through the core layer or disposed in an aperture or feature thereof, can be bonded directly to a structural layer of the composite enclosure by any of the methods described herein. Thus, in some examples, the structural layer can overlie or occlude an aperture or other feature of the core layer, in which a functional component can be at least partially disposed. In such examples, the functional component can also, in some embodiments, be bonded to the core layer.

The position of the functional component in a feature of the core layer, such as an aperture, and the resultant proximity of the functional component and the structural layer and exterior coating, can result in a relatively small distance between at least a portion of the functional component and an exterior surface of the composite enclosure, as described herein. For example, the distance between a portion of a functional component of a composite enclosure and an exterior surface thereof can be between about 0.07 mm and about 1 mm, between about 0.1 mm and about 0.5 mm, or between about 0.13 mm and about 0.3 mm. In some examples, the distance between a portion of a functional component of a composite enclosure and an exterior surface thereof can be between about 0.1 mm and about 0.13 mm. As described herein, this range of distances can result in enhanced performance and can contribute to the advantageous properties of the composite enclosures described herein.

In some examples, a composite enclosure can optionally include one or more additional structural layers. In some examples, a second structural layer can include a substantially similar material to the first structural layer and can have substantially similar dimensions, but can be disposed on a portion of the core layer opposite the first structural layer. In some examples, a second structural layer can overlie or occlude the core layer, functional component, and/or any other feature in which all or a portion of a functional component can be disposed. In some examples, a second structural layer can be bonded to the core layer and/or functional component, for example, by adhesives, welding, brazing, and/or any other appropriate bonding methodology.

In some examples where a composite enclosure includes a first structural layer and a second structural layer disposed on opposite sides, surfaces, or faces of a core layer, the structural layers can cooperate to at least partially enclose the core layer and/or any functional component. This construction of a composite device enclosure, with two structural layers spaced apart from one another by a core layer and bonded thereto, can provide increased relative levels of mechanical strength, resistance to bending, and resistance to denting when compared to an enclosure that includes only a single core layer and no structural layers. Further, this layered construction can result in device enclosures that exhibit superior mechanical properties relative to substantially monolithic components, while at the same time being lighter and/or easier to manufacture.

Reference will now be made in detail to representative embodiments illustrated in the accompanying drawings. It should be understood that the following descriptions are not intended to limit the embodiments to one preferred embodiment. To the contrary, the present disclosure is intended to cover alternatives, modifications, and equivalents as can be included within the spirit and scope of the described embodiments, as defined by the appended claims.

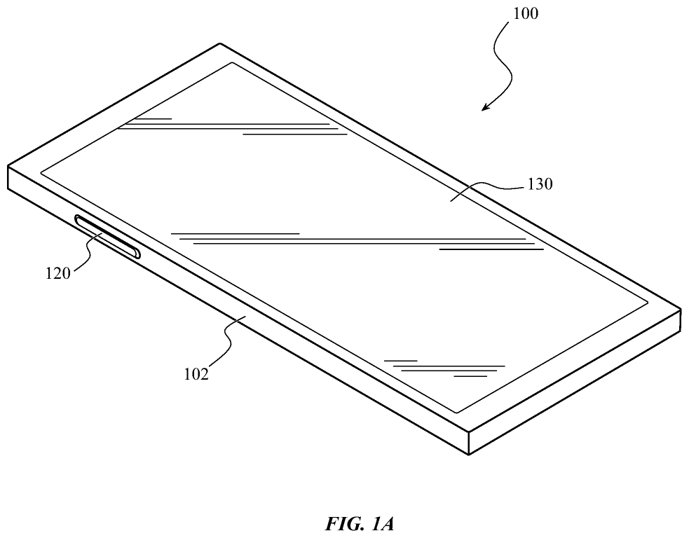

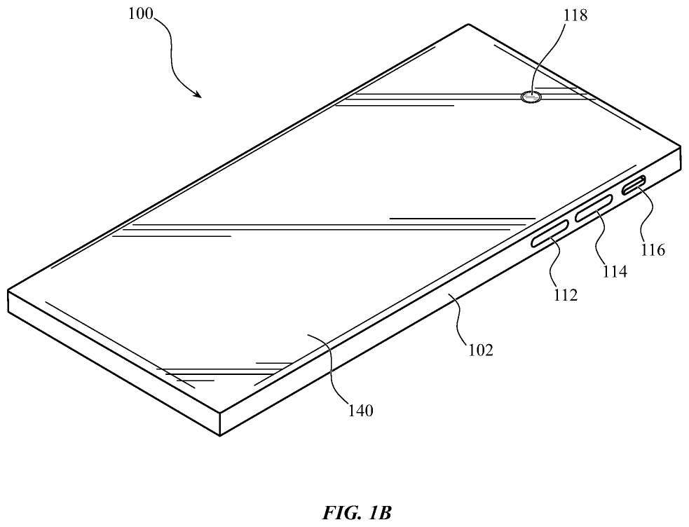

FIGS. 1A and 1B illustrate a front perspective view, and a rear perspective view, respectively, of an embodiment of an electronic device 100. The electronic device 100 shown in FIG. 1A is a mobile wireless communication device, such as a smartphone. The smartphone of FIG. 1A is merely one representative example of a device that can be used in conjunction with the systems and methods disclosed herein. The electronic device 100 can correspond to any form of wearable electronic device, a portable media player, a media storage device, a portable digital assistant (“PDA”), a tablet computer, a computer, a mobile communication device, a GPS unit, a remote control device, or other electronic device. The electronic device 100 can be referred to as an electronic device, or a consumer device.

The electronic device 100 can include a display assembly 130 that is covered by a protective cover 132. The display assembly 130 can include multiple layers, with each layer providing a unique function. The display assembly 130 can be partially covered by a border or a frame that extends along an outer edge of the protective cover 132 and partially covers an outer edge of the display assembly 130. The border can be positioned to hide or obscure any electrical and/or mechanical connections between the layers of the display assembly 130 and flexible circuit connectors. Also, the border can have a uniform thickness. For example, the border can include a thickness that generally does not change in the X- and Y-dimensions. The protective cover 132 of the electronic device can define a portion of the exterior surface of the device 100. Additionally, the electronic device 100 can include a power or other input button 120.

A rear perspective view of the electronic device 100 is shown in FIG. 1B. The electronic device 100 can have a housing that includes a band or a frame 102 that defines an outer perimeter of the electronic device 100. In some examples, the band 102 can include several sidewall components that can be joined or bonded together to form the band 102. As described further herein, the housing can further include a back portion, such as a back cover or backplate 140. The backplate 140 can be a composite backplate, as described herein, including an exterior layer, a structural layer, and a core layer and/or functional component.

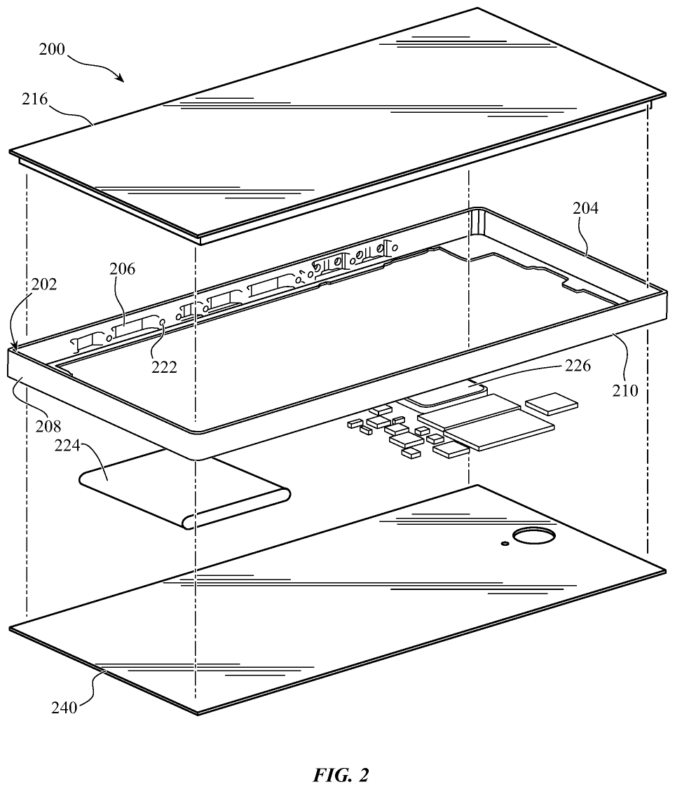

The electronic device 100 can also include several control inputs designed to facilitate transmission of a command to the electronic device 100. For example, the electronic device 100 can include a first control input 112 and a second control input 114. The aforementioned control inputs can be used to adjust the visual information presented on the display assembly 130 or the volume of acoustical energy output by an audio module, as non-limiting examples. Additionally, a mute or lock switch 116 can be included in the controls accessible on the exterior surface of the electronic device 100. The controls can include one of a switch or a button designed to generate a command or signal that is received by a processor. The control inputs can at least partially extend through openings in the sidewall components. Furthermore, a camera unit 118 can be included in the electronic device, passing through the backplate 140, as shown in FIG. 1B. Further details regarding the features and structure of an electronic device are provided below, with reference to FIG. 2.

FIG. 2 illustrates an exploded view of an electronic device 200. The electronic device 200 shown in FIG. 2 is a smartphone, but is merely one representative example of a device that can include or be used with the systems and methods described herein. As described with respect to electronic device 100, electronic device 200 can correspond to any form of wearable electronic device, a portable media player, a media storage device, a portable digital assistant (“PDA”), a tablet computer, a computer, a mobile communication device, a GPS unit, a remote control device, and other similar electronic devices. In some examples, the electronic device 200 can include some or all of the features described herein with respect to electronic device 100.

The electronic device 200 can have a housing that includes a band 202, which at least partially defines an exterior portion, such as an outer perimeter, of the electronic device. As with the band 102 described above in FIGS. 1A-1B, the band 202 can include several sidewall components. The band 202 can also include a non-metal material or materials that separate and/or join the sidewall components of the band 202 with each other.

The housing, including the band 202, can include one or more features to receive or couple to other components of the device 200, such as structural feature 222. For example, the band 202 can include any number of features such as apertures, cavities, indentations, and other mating features to receive and/or attach to one or more components of the device 200. The electronic device 200 can include internal components such as processors, memory, circuit boards, batteries, and sensors. Such components can be disposed within an internal volume defined, at least partially, by the band 202, and can be affixed to the band 202, by internal surfaces, attachment features such as structural feature 222, threaded connectors, studs, posts, and/or other fixing features, that are formed into, defined by, or otherwise part of the band 202.

The device 200 can include internal components, such as a system in package (SiP) 226, including one or more integrated circuits such as a processors, sensors, and memory. The device 200 can also include a battery 224 housed in the internal volume of the device 200. The device 200 can also include one or more sensors, such as optical or other sensors, that can sense or otherwise detect information regarding the environment exterior to the internal volume of the device 200. Additional components, such as a haptic engine, can also be included in the device 200. The electronic device 200 can also include a display assembly 216, similar to display assembly 130 described herein. In some examples, the display assembly 216 can be received by and/or be attached to the band 202 by one or more attachment features.

An exterior surface of the electronic device 200 can further be defined by a back cover 240, which can be coupled to the band 202. In this regard, the back cover 240 can combine with the band 202 to form an enclosure or housing of the electronic device 200, with the enclosure or housing (including band 202 and back cover 240) at least partially defining an internal volume. The back cover 240 and/or band 202 can be have a composite and/or functional composite construction, as described herein, including an exterior layer, one or more structural layers, and one or more functional components. In some examples, the back cover or backplate 240 can be coupled to the band 202 by any suitable means, including by attachment features formed in the band 202 and/or backplate 204, by an adhesive, by welding, brazing, or any other appropriate coupling material or process.

The housing, including the backplate 240 having a composite construction, as described herein, can be conformed to interior dimensional requirements, as defined by the internal components. For example, the structure of the housing including a composite backplate 240 can be defined or customized exclusively or primarily by the internal components the housing is designed to accommodate. Since a housing with a composite backplate 240 can be extremely light and strong, the housing can be shaped to house the interior components in a dimensionally efficient manner without being constrained by factors other than the dimensions of the components, such as the need for additional structural elements. The composite backplate 240 can be formed by a variety of processes, as discussed herein. In some embodiments, these formation processes can allow for the housing and/or backplate 240 to have a detailed shape or design that is tailored specifically to satisfy one or more needs, such as internal dimensional requirements, without the need for additional features to reinforce the structure of the housing. Additionally, artifacts of the manufacturing process of the housing can be eliminated.

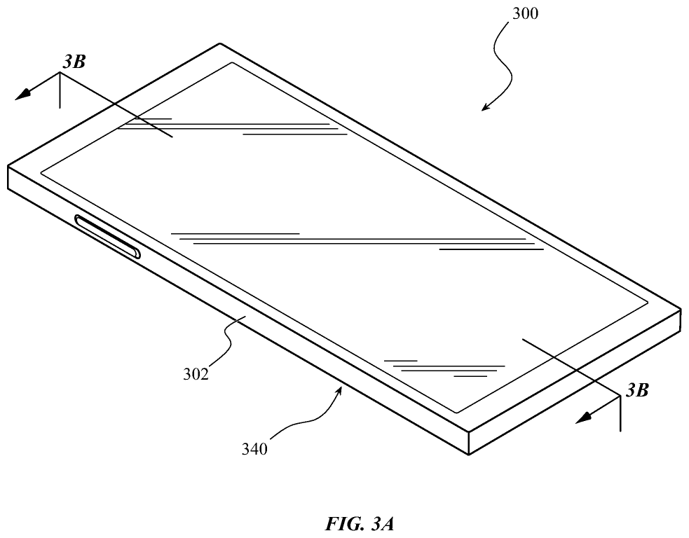

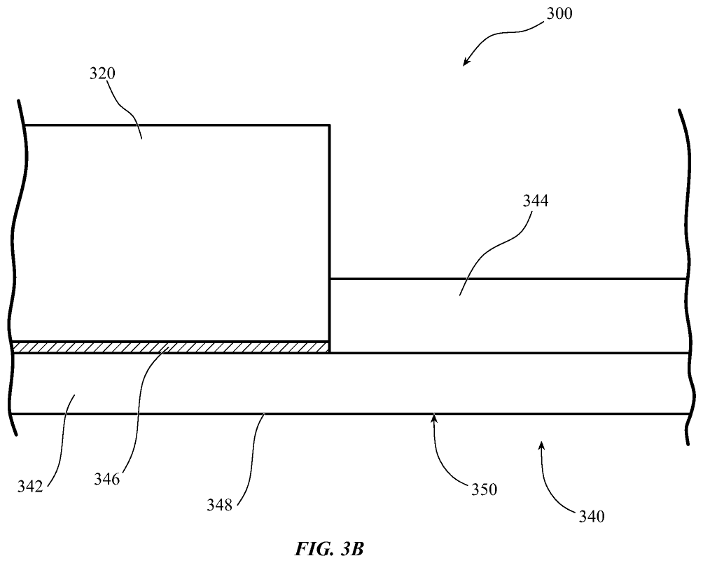

While any number or variety of components of an electronic device, such as electronic device 200, can be formed from or can include the composite construction described herein, the structure of these composite components can be, for example, a composite component including an exterior layer, a structural layer, and a core layer including a functional component as described herein. The structure and materials of the exterior layer, structural layer, core layer, and functional component, as well as the composite component itself, can apply to not only to the specific examples discussed herein, but to any number or variety of embodiments in any combination. Various embodiments of composite components are described below, with reference to FIGS. 3A and 3B.

FIG. 3A illustrates a front perspective view of an embodiment of an electronic device 300. The electronic device 300 can include some or all of the features of electronic devices 100 and 200, as discussed herein. For example, the electronic device 300 includes a backplate portion 340 and a band 302. The electronic device 300 shown in FIG. 3A is a mobile wireless communication device, such as a smartphone. The smartphone of FIG. 3A is merely one representative example of a device that can be used in conjunction with the systems and methods disclosed herein. Electronic device 300 can correspond to any form of wearable electronic device, a portable media player, a media storage device, a portable digital assistant (“PDA”), a tablet computer, a computer, a mobile communication device, a GPS unit, a remote control device, or other electronic device.

FIG. 3B illustrates a simplified schematic cross-sectional view of a backplate portion 340 of an enclosure for an electronic device 300 along line B-B. In some examples, the backplate 340 can include some or all of the features of back covers or backplates 140 and 240 described above. The backplate 340 at least partially defines an exterior surface 350 of the electronic device 300. Although not illustrated, additional components, such as a display or structural components, can be included in the device 300 and positioned within the internal volume at least partially defined by the backplate 340.

As can be seen, the backplate 340 includes a first structural layer 342. The first structural layer can include one or more materials such as a fiber reinforced polymer material, fiberglass material, carbon fiber material, fiberglass-carbon fiber hybrid material, metal, such as aluminum, steel, titanium, or other desired structural materials. An exterior layer 348 can be bonded to the first structural layer 342 and can at least partially define an exterior surface 350 of the device 300. The exterior layer can include a ceramic coating, paint coating, physical vapor deposited (PVD) coating, glass, metal, or any other desired exterior materials.

A core layer 344, similar to other core layers described herein, can be bonded to the first structural layer 342, and can at least partially define an internal volume of the electronic device 300. The core layer 344 can include an aperture, a gap, a recess, or another feature in which a functional component 320 can be at least partially disposed. In some examples, this feature can be formed by a subtractive process. In some other examples, however, the core layer 344 can be formed by an additive process around the functional component 320 and or the feature for receiving the functional component 320. As can be seen in FIG. 3B, the functional component 320, such as a magnet, for example, can at least partially pass through the core layer 344, where it can be bonded to the first structural layer 342. In this example, the functional component 320 is boned to the first structural layer 342 by an epoxy adhesive 346, although any suitable method of bonding can be used. Thus, the first structural layer 344 and the functional component 320are bonded to the first structural layer 342, by adhesive 346, and provide mechanical support thereto. In this way, and as described herein, the core layer 344 and functional component 320 can cooperate to add support to the first structural layer 342 and exterior layer 348, thereby allowing for a reduced thickness for these layers as compared to a backplate 340 that relies solely on the material of the first structural layer 342 and/or exterior layer 348 for structural support.

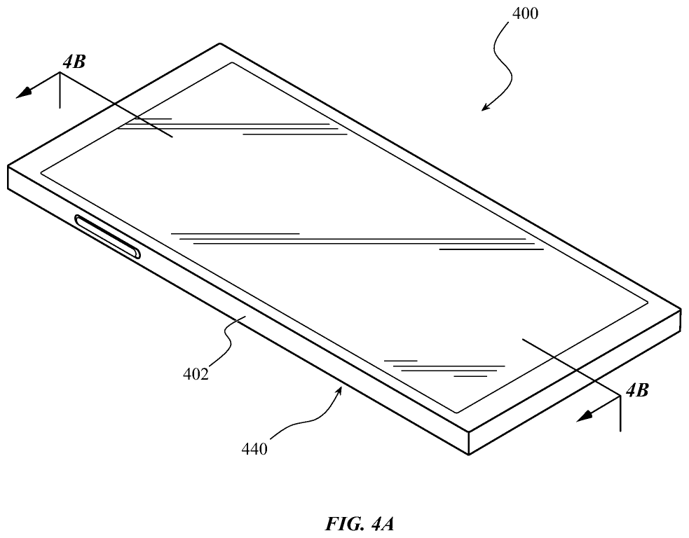

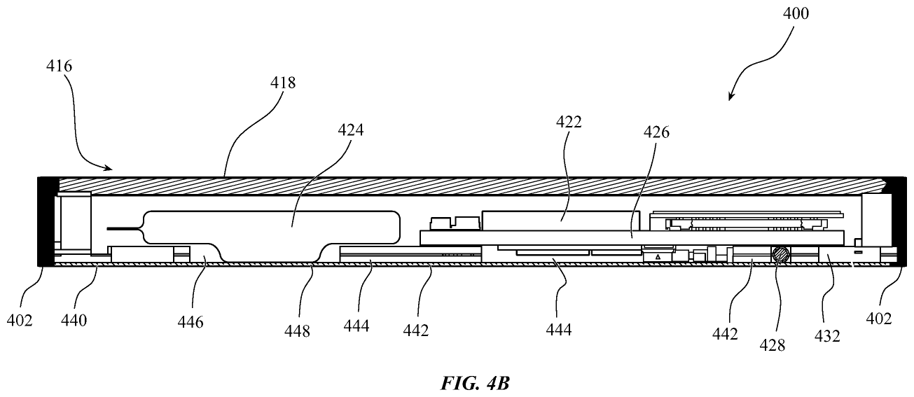

The components and concepts illustrated in FIGS. 3A-B can be applied to any of the composite enclosures described herein, in any combination. Further examples, including the concepts and features discussed with respect to FIGS. 3A-B, are described below with reference to FIGS. 4A-11.

FIG. 4A illustrates a front perspective view of an embodiment of an electronic device 400. The electronic device 400 can include some or all of the features of electronic devices 100, 200, or 300 discussed herein. The electronic device 400, shown in FIG. 4A, is a mobile wireless communication device, such as a smartphone. The smartphone of FIG. 4A is merely one representative example of a device that can be used in conjunction with the systems and methods disclosed herein. Electronic device 400 can correspond to any form of wearable electronic device, a portable media player, a media storage device, a portable digital assistant (“PDA”), a tablet computer, a computer, a mobile communication device, a GPS unit, a remote control device, or other electronic device. As shown, the electronic device 400 includes a band 402 similar to bands 102, 202 described herein, and a back cover or backplate 440 that can be a functional composite backplate 440. Further details of the electronic device 400 are provided below, with reference to FIG. 4B.

FIG. 4B illustrates a cross-sectional view of electronic device 400 along line B-B, as shown in FIG. 4A. The electronic device 400 can be substantially similar to and include some or all of the features of electronic devices 100, 200, and 300, as described herein. The device 400 can include a display assembly 416, including a protective cover 418 that can at least partially define an exterior surface of the device 400. The enclosure of the device 400 can include, for example, a band 402 similar to bands 102 and 202 described herein, and a back cover or backplate 440 that can be a functional composite backplate 440. The backplate 440 can include a structural layer 442 bonded to an exterior layer 448. The structural layer 442 can also be bonded to a core layer 444, as shown in FIG. 4B. The exterior layer 448 can at least partially define an exterior surface of the device 400, in this case, a major surface opposite the surface defined by the protective cover 418.

The core layer 444 of the backplate 440 can further include any number of gaps, apertures, recesses, or other features 446 in which one or more functional components can be disposed, though some gaps, apertures, recesses, or other features 446 can be free of functional components. For example, the device 400 can include a battery 424 that can have a least a portion thereof disposed in the aperture 446 of the core layer 444. As described, for example with respect to FIG. 3B, the battery 424 can be bonded directly to the structural layer 442 and can provide support thereto. In some examples, components can be positioned within a feature or aperture 446 defined by the core layer 444, without being bonded directly to the structural layer 442. For example, the device 400 can include a two-sided logic board 426 that can include a system on a chip (SOC) 422. The SOC 422 and logic board 426 can be bonded or fastened to attachment features of the enclosure, and/or can be bonded to the core layer 444, and can extend at least partially into the aperture 446, as shown. In some examples, however, it can be desirable for a component, such as logic board 426, not to directly contact the structural layer 442. For example, it can be desirable for a component 426 to be thermally isolated from the exterior of the device 400. In some examples, a filler material can be included in the aperture 446 to at least partially fill the aperture 446 and to at least partially surround the component 426, thereby providing additional mechanical support or to thermally couple or isolate the component 426.

The device 400 can also include functional components, such as an antenna 428, which can be positioned in an aperture of the core layer 444. In this example, such a position of the antenna 428 can allow for enhanced performance when receiving and/or transmitting wireless signals. Further, in some examples, the core layer 444 can include a material that is not electromagnetically transparent. In these examples, the structural layer 442 and the exterior layer 448 can include an electromagnetically transparent material. The aperture in the core layer 444 in which the antenna 428 is disposed can provide an area through which electromagnetic signals can be transmitted or received by the antenna 428 through the structural layer 442 and exterior layer 448, without sacrificing or significantly reducing the mechanical properties of the backplate 440. According to this example, the antenna 428 can be bonded to the structural layer 442 through the core layer 444 to cooperate with the core layer 444 to support the structural layer 442 and exterior layer 448 at that location.

In some examples, a device 400 can also include a functional component such as a magnet 432. Similar to the antenna 428, the magnet 432 can be positioned in an aperture of the core layer 444 and can be bonded directly to the structural layer 442. Accordingly, only the structural layer 442 and exterior layer 448 of the backplate 440 separate the magnet 432 from the exterior surface of the device. This allows for improved magnetic field strength at this portion of the exterior surface, while still providing mechanical support because the direct bonding of the magnet 432 to the structural layer 442 causes forces to be directed through the structural layer 442 to the magnet 432.

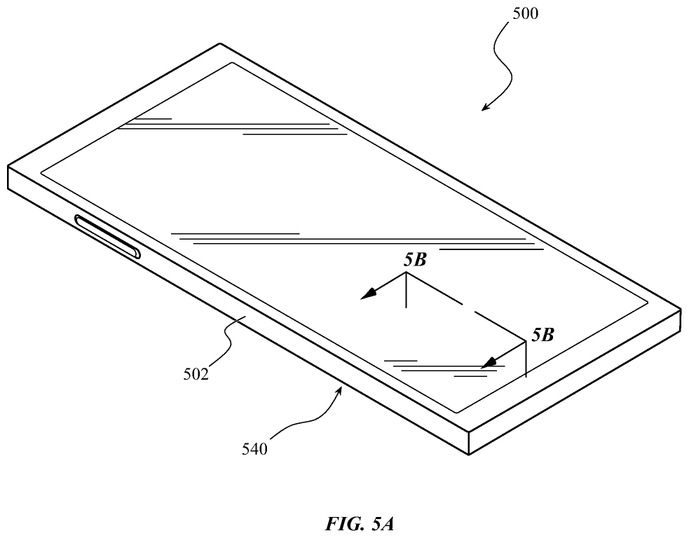

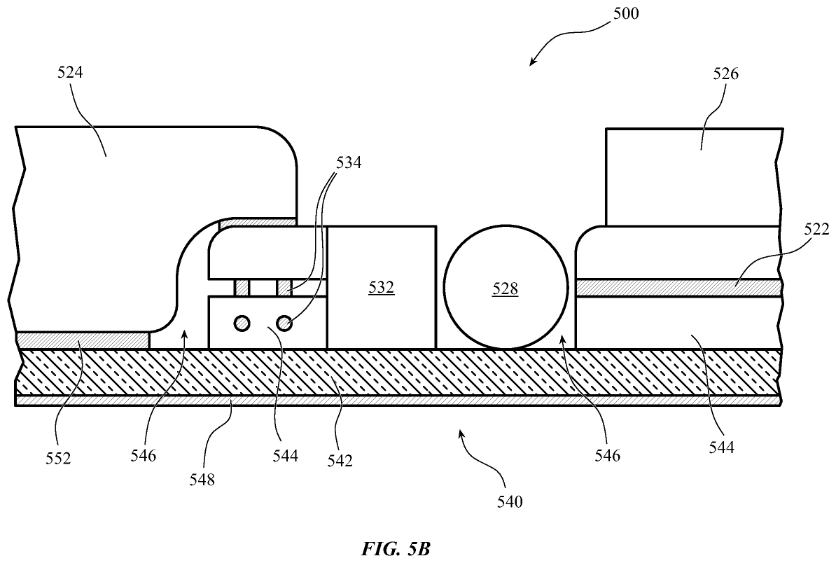

While any number or variety of components of an electronic device, such as electronic device 400, can be formed from or can include the composite construction described herein, the structure of these composite components can be, for example, a composite component including an exterior layer, a structural layer, and a core layer including a functional component, as described herein. The structure and materials of the exterior layer, structural layer, core layer, and functional component, as well as the composite component itself, can apply to not only to the specific examples discussed herein, but to any number or variety of embodiments in any combination. Various embodiments of composite components are described below, with reference to FIGS. 5A-5B.

FIG. 5A illustrates a front perspective view of an embodiment of an electronic device 500. The electronic device 500 can include some or all of the features of electronic devices 100, 200, 300, or 400, as discussed herein. The electronic device 500 shown in FIG. 5A is a mobile wireless communication device, such as a smartphone. The smartphone of FIG. 5A is merely one representative example of a device that can be used in conjunction with the systems and methods disclosed herein. Electronic device 500 can correspond to any form of wearable electronic device, a portable media player, a media storage device, a portable digital assistant (“PDA”), a tablet computer, a computer, a mobile communication device, a GPS unit, a remote control device, or other electronic device. The electronic device includes a band 502 similar to bands 102, 202, and 402 described herein, and a back cover or backplate 540 that can be a functional composite backplate 540. Further details of the electronic device 500 are provided below, with reference to FIG. 5B.

FIG. 5B illustrates a close-up cross-sectional view of an electronic device 500, along line B-B. The electronic device 500 can be substantially similar to, and can include some or all of the features of electronic device 400, as described herein. Further, the view shown in FIG. 5B is similar to the view of electronic device 400 illustrated in FIG. 4B, taken along a major axis of the device 500, but showing a close-up of a portion of the bottom portion of the device 500. The device 500 can include a back cover or backplate 540 that can be a functional composite backplate 540, as detailed herein. The functional composite backplate 540 can include a structural layer 542 and an exterior layer 548. The structural layer 542 can also be bonded to a core layer 544 as described herein. The exterior layer 548 can at least partially define an exterior surface of the device 500, in this case, a major surface opposite a surface including a display.

As can be seen, the core layer 544 can define and include a gap, aperture, recess, or other feature 546, in which one or more functional components of the device 500 can be at least partially disposed. In FIG. 5B, two apertures 546 defined by the core layer 544 are illustrated, although the core layer 544 can include any number of gaps, apertures, recesses, or other features. The device 500 can include a battery 524 that can pass through the aperture 546 of the core layer 544, where it can be bonded to the structural layer 542, for example by an epoxy adhesive 552, although any method of bonding can be used. As described, for example with respect to FIG. 3, the battery 524 can thus provide support to the structural layer 542. The device 500 can also include functional components, such as an antenna 528, which can be positioned in an aperture 546 of the core layer 544. As described with respect to FIG. 4, such a position of the antenna 528 can allow for enhanced performance when receiving and/or transmitting wireless signals. Additionally, the antenna 528 can be bonded to the structural layer 542 through the core layer 544 to cooperate with the core layer 544 in supporting the structural layer 542 and exterior layer 548 at that location. The device 500 can further include a magnet 532, such as a bonded magnet, as described herein. As with the antenna 528, the magnet 532 can be positioned in an aperture 546 of the core layer 544 and can extend therethrough to contact or be bonded directly to the structural layer 542.

In some examples, the features 546 of the core layer 544 can be sized precisely to correspond to the shape of the functional components. Further, in some examples, a feature 546 of the core layer 544 can extend in any direction through the core layer 544, as desired, such as passing laterally through a portion of the core layer 544. As can be seen in FIG. 5, in some examples, the device 500 can include one or more vias 534 that can relay signals between one or more components of the device 500. In some examples, a via 534 can enter a feature of the core layer 544, for example by a hole in a surface thereof, and extend through the core layer 544 to a desired location, whereupon the via 534 can exit the core layer 544 and connect to a component. In this case, a portion of the via 534 can thus be embedded in, and surrounded by, the material of the core layer 544. In some examples, this can be achieved by subtractive processes, whereupon material can be removed from the core layer 544 and a functional component such as a via 534 can be disposed in the resultant feature. In some examples, however, the core layer 544 can be formed by an additive process, such as molding, printing, or any other additive process that deposits the core layer material around a functional component, such as a via 534.

In some examples, the device 500 can also include one or more functional components that can contact or be bonded or otherwise coupled to the core layer 544, such as a thermal component 522, which can be, for example, a thermal spreader. In some examples, the device can include a thermal spreader 522 to distribute or transmit heat generated by one or more components, such as a logic board 526, to which the thermal spreader 522 can be coupled. As can be seen, in some examples, the thermal component 522 can be bonded to the core layer 544, for example, by a layer of adhesive. Accordingly, in some examples, a functional component such as thermal spreader 522 can serve to provide additional mechanical or structural support to the backplate 540, through the core layer 544. Thus, although not bonded directly to the structural layer 542, a component such as thermal spreader 522 can perform a structural support function for at least a portion of the backplate 540 in addition to any thermal function it primarily serves. This added support allows for a thinner structural layer 542 and exterior layer 548, reducing the overall thickness of the device 500.

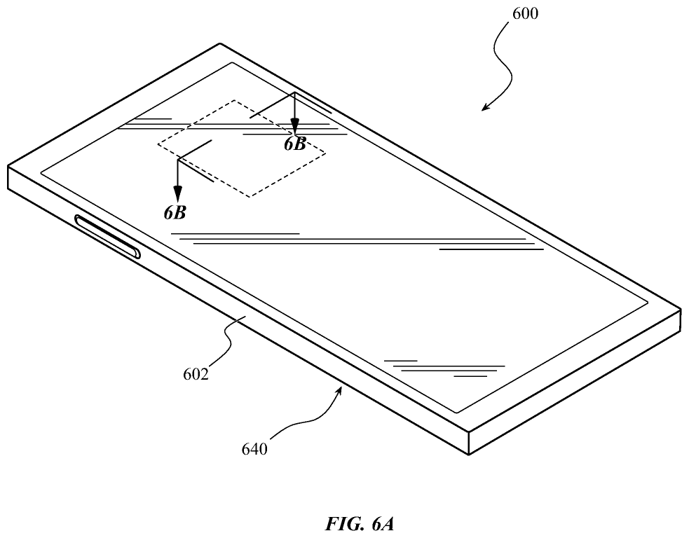

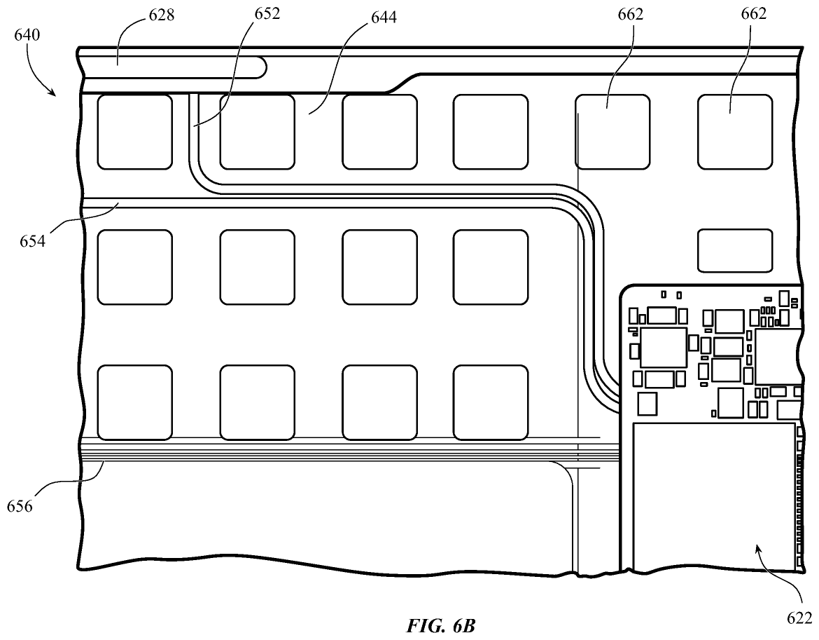

While any number or variety of components of an electronic device, such as electronic devices 100, 200, 300, 400, and/or 500 can be formed from or can include the composite construction described herein, the structure of these composite components can be, for example, a composite component including an exterior layer, a structural layer, and a core layer including a functional component as described herein. The structure and materials of the exterior layer, structural layer, core layer, and functional component, as well as the composite component itself, can apply to not only to the specific examples discussed herein, but to any number or variety of embodiments in any combination. Various embodiments of composite components are described below, with reference to FIGS. 6A-B.

FIG. 6A illustrates a front perspective view of an embodiment of an electronic device 600. The electronic device 600 can include some or all of the features of electronic devices 100, 200, 300, 400, or 500 discussed herein. The electronic device 600 shown in FIG. 6A is a mobile wireless communication device, such as a smartphone. The smartphone of FIG. 6A is merely one representative example of a device that can be used in conjunction with the systems and methods disclosed herein. Electronic device 600 can correspond to any form of wearable electronic device, a portable media player, a media storage device, a portable digital assistant (“PDA”), a tablet computer, a computer, a mobile communication device, a GPS unit, a remote control device, or other electronic device. The electronic device includes a band 602 similar to bands 102, 202, 402, and 502 described herein, and a back cover or backplate 640 that can be a functional composite backplate 640. Further details of the electronic device 600 are provided below, with reference to FIG. 6B.

FIG. 6B shows a cut away top view of the area 6B shown in FIG. 6A, illustrating a top view of a backplate 640 of an electronic device 600. The device 600 can be substantially similar to the devices 400, 500 described herein. In some examples, although not visible, the backplate 640 can include a structural layer and an exterior layer that are bonded to the core layer 644, as described herein. The present cut-away view shows only a portion of the core layer 644. Some or all of the features and functional components illustrated can be substantially entirely surrounded or occluded by additional core layer 644 material and/or a structural layer, as described herein. Further, the device 600 can include a logic board 622 that can overlie and/or be bonded to the core layer 644.

As shown in FIG. 6B, the core layer 644 can include a number of features in which all or a portion of any number of functional components can be disposed. In this case, the core layer 644 of the backplate 640 can include a number of magnets 662 that can be disposed in apertures formed in the core layer 644. These magnets 662 can be arranged in any desired formation and can include any desired shape. In some examples, as described herein, the magnets 662 can provide for the magnetic attachment of accessories or modules to the external surface of the device 600, at any of the locations of the magnets 662.

The core layer 644 can include an antenna 628 at least partially embedded or incorporated therein. In some examples, the backplate 640 can include any number of relays, wires, cables, or vias at least partially embedded in the core layer 644. In some examples, the backplate 640 can include cables 652, 654 that are embedded in the core layer 644 and that can transmit power and/or signals between one or more components of the device 600. In this case, the cables 652, 654 can be connected to the logic board 622 and can also be connected to other components, such as a battery. In some examples, portions of the cables 652, 654 can be entirely surrounded by, or embedded in, the core layer 644, while some other portions can extend out of the core layer and might not contact the core layer 644 at all. The device 600 can additionally include vias or relays 656 that can be connected to one or more components of the device, such as the logic board 622. These vias or relays 656 can extend through the core layer 644, as described, to provide additional functionality to the backplate 640 without sacrificing or substantially impairing the structural functions of the backplate 640.

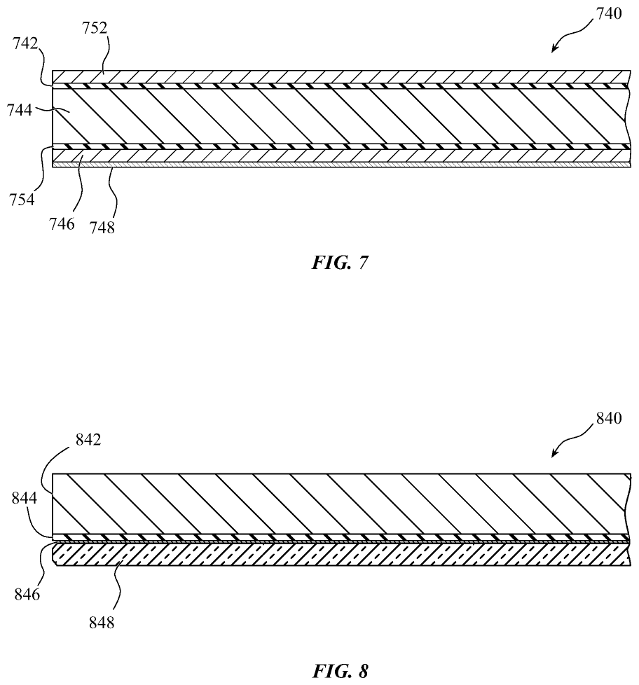

While any number or variety of components of an electronic device, such as electronic devices 100, 200, 300, 400, 500, and/or 600, can be formed from or can include the composite construction described herein, the structure of these composite components can be, for example, a composite component including an exterior layer, a structural layer, and a core layer including a functional component as described herein. The structure and materials of the exterior layer, structural layer, core layer, and functional component, as well as the composite component itself, can apply to not only to the specific examples discussed herein, but to any number or variety of embodiments in any combination. Various embodiments of composite components are described below, with reference to FIG. 7.

FIG. 7 illustrates a cross sectional view of a portion of a backplate 740 of a housing of an electronic device, for example electronic devices 100, 200, 300, 400, 500, and/or 600, as described herein. The backplate 740 can include a first structural layer 746 having an exterior layer 748 formed thereon. As described herein, the exterior layer 748 can at least partially define an exterior surface of the housing of an electronic device. In some examples, the first structural layer 746 can include a metal material, such as steel, titanium, aluminum, or other metals. In some examples, any suitable metal can be used as the first structural layer.

The exterior layer 748 can be a layer or coating that is formed directly on or otherwise bonded to the first structural layer 746. For example, in some examples, the exterior layer 748 can include a paint layer, an anodized layer, a PVD layer, such as a metallic PVD layer, a ceramic coating, or a polymer coating. In some examples, the combined first structural layer 746 and exterior layer 748 can have a combined thickness of from about 0.07 mm to about 1 mm, from about 0.1 mm to about 0.5 mm, or from about 0.13 mm to about 0.3 mm. In some examples, the combined first structural layer 746 and exterior layer 748 can have a thickness of about 0.1 mm or about 0.13 mm.

The backplate 740 can also include a core layer 744 that is bonded to the first structural layer 746. The core layer 744 and first structural layer 746 can be bonded to one another by any suitable means, such as by an adhesive, by brazing, welding, or another appropriate bonding method. In some examples, and as illustrated, the core layer 744 can be bonded to the first structural layer 746 by a layer of adhesive 754. In some examples, the adhesive 754 can be an epoxy or resin adhesive.

As described herein, in some examples, a core layer can include or incorporate a functional component. In some examples, and as illustrated, the core layer 744 can itself be the functional component. The core layer 744 can include, for example, magnetic material or can be a magnet. In some examples, the core layer 744 can be a bonded magnet. That is, in some examples, the core layer 744 can be a magnet that includes a magnetic material, such as magnetic powder, bonded together by a binder, for example an epoxy or resin binder. In some examples, the magnetic material can include neodymium alloy, strontium alloy, or samarium—cobalt alloy material. In yet other examples, the functional component 744 can be any of the functional components described herein.

Because of the thicknesses of the first structural layer 746 and the exterior layer 748, as described herein, the core layer or functional component 744 can be disposed about 0.07 mm to about 1 mm from an exterior surface of the backplate 740, about 0.1 mm to about 0.5 mm, or from about 0.13 mm to about 0.3 mm from the exterior surface of the backplate 740. In some examples, the core layer or functional component 744 can be about 0.1 mm or about 0.13 mm from the exterior surface of the backplate.

As described herein, the relatively small distance between the core layer or functional component 744 and the exterior surface of the backplate 740 can allow for the use of a functional component that has a lower level of performance than a traditional component used with a traditional backplate. While the thickness of a traditional backplate of an electronic device necessitates the use of a comparatively strong sintered magnet to achieve a desired level of performance or magnetic field at the exterior of the backplate, in some examples, the backplate construction described herein can allow for the use of a bonded magnet, such as core layer 744, to achieve a substantially similar level of performance.

In some examples, the backplate 740 can include a second structural layer 752 overlying and/or bonded to the core layer or functional component 744. In some examples, the second structural layer 752 can be substantially similar to or the same as the first structural layer 746, without an exterior layer or coating. For example, in some examples, the second structural layer 752 can include a metal material, such as steel, titanium, aluminum, or other suitable metals. Further, in some examples, the second structural layer 752 can be bonded to the core layer or functional component 744 in a similar manner to the first structural layer 746. In some examples, the second structural layer 752 can be bonded to the core layer or functional component 744 by an adhesive layer 742, such as an epoxy or resin layer.

While any number or variety of components of an electronic device, such as backplate 740, can be formed from or can include the composite construction described herein, the structure of these composite components can be, for example, a composite component including an exterior layer, a structural layer, and a core layer including a functional component, as described herein. The structure and materials of the exterior layer, structural layer, core layer, and functional component, as well as the composite component itself, can apply to not only to the specific examples discussed herein, but to any number or variety of embodiments in any combination. Various embodiments of composite components are described below, with reference to FIG. 8.

FIG. 8 illustrates a cross section of a portion of a backplate 840 of a housing of an electronic device, for example electronic devices 100, 200, 300, 400, 500, and/or 600 as described herein. The backplate 840 can include an exterior layer 848. As described herein, the exterior layer 848 can at least partially define an exterior surface of the housing of an electronic device. In some examples, and as illustrated in FIG. 8, the exterior layer 848 can include a ceramic or glass material. In some examples, the exterior layer 848 can include sapphire. Further, in some examples, the exterior layer 848 can include a layer or coating 846 deposited or formed on a surface of the exterior layer 848 opposite the exterior surface of the backplate 840. In some examples, the layer or coating 846 can be a cosmetic layer, that is, a layer that provides a desired cosmetic appearance to the backplate 840, for example when viewed through the exterior layer 848. Accordingly, in some examples, the layer 846 can be an ink or a paint layer, such as a polymer-based ink. In some examples, the exterior layer 848 and its associated coating 846 can have a combined thickness of from about 0.07 mm to about 1 mm, from about 0.1 mm to about 0.5 mm, or from about 0.13 mm to about 0.3 mm. In some examples, the combined exterior layer 848 and associated layer or coating 846 can have a thickness of about 0.1 mm or about 0.13 mm.

The backplate 840 can also include a structural layer 842 bonded to the exterior layer 848. In some examples, the structural layer 842 can include a metal material, such as steel or titanium. In some examples, any suitable metal, such as aluminum, can be used as the structural layer 842. Although described as a structural layer, in some examples, the structural layer 842 can serve a similar function to, or include any of the features of, a core layer, as described herein. For example, the structural layer 842 can include one or more functional components, and/or can include any number of apertures, gaps, recesses, or spaces through which at least a portion of a functional component can pass to engage with or bond to the exterior layer 848. The structural layer 842 and the exterior layer 848 (and any of its intermediate layers) can be bonded to one another by any suitable means, such as by an adhesive, by brazing, welding, or another appropriate bonding method. In some examples, and as illustrated in FIG. 8, the structural layer 842 can be bonded to the exterior layer 848 by a layer of adhesive 844. In some examples, the adhesive 844 can be an epoxy or resin adhesive.

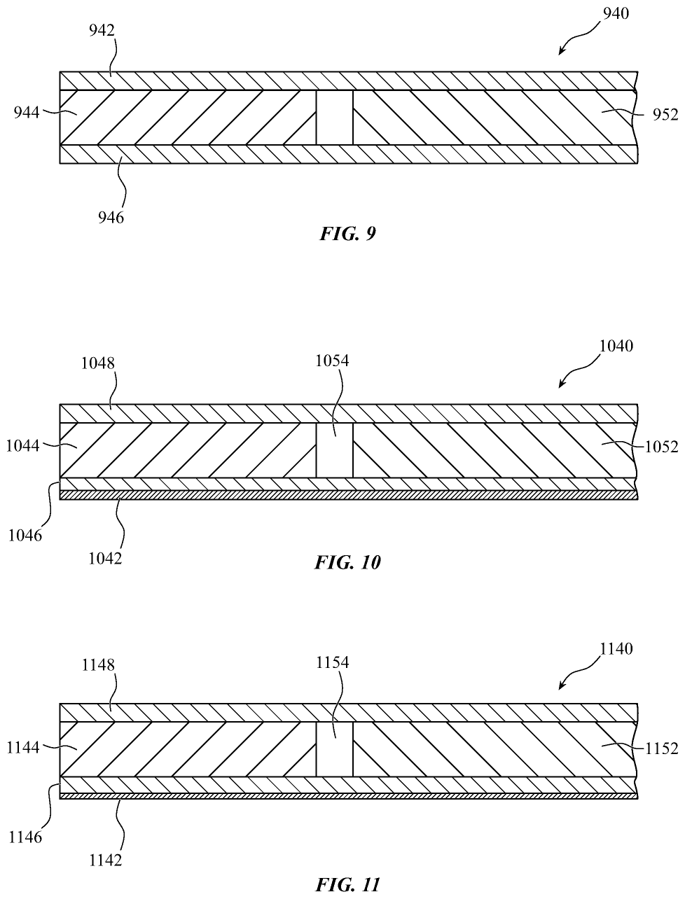

While any number or variety of components of an electronic device, such as backplate 840, can be formed from or can include the composite construction described herein, the structure of these composite components can be, for example, a composite component including an exterior layer, a structural layer, and a core layer including a functional component as described herein. The structure and materials of the exterior layer, structural layer, core layer, and functional component, as well as the composite component itself, can apply to not only to the specific examples discussed herein, but to any number or variety of embodiments in any combination. Various embodiments of composite components are described below, with reference to FIGS. 9-11.

FIG. 9 illustrates a cross sectional view of a portion of a backplate 940 of a housing of an electronic device, for example electronic devices 100, 200, 300, 400, 500, and/or 600, as described herein. The backplate 940 can include a first structural layer 946 that can also serve as an exterior layer that can at least partially define an exterior surface of the housing of an electronic device. In some examples, the first structural layer 946 can include a fiber reinforced composite material, such as a fiber reinforced polymer material, fiberglass material, carbon fiber material, fiberglass-carbon fiber hybrid material, or another fiber reinforced material. Although not illustrated, in some examples the first structural layer 946 can include an exterior layer or coating deposited or formed thereon. For example, in some examples, the first structural layer 946 can include a paint layer, an anodized layer, a PVD layer, such as a metallic PVD layer, a ceramic coating, or a polymer coating. In some examples, the combined first structural layer 946 and any exterior layer or coating can have a combined thickness of from about 0.07 mm to about 1 mm, from about 0.1 mm to about 0.5 mm, or from about 0.13 mm to about 0.3 mm. In some examples, the combined first structural layer 846 and exterior layer 848 can have a thickness of about 0.1 mm or about 0.13 mm.

The backplate 940 can also include a core layer 944 that is bonded to the first structural layer 946. The core layer 944 and the first structural layer 946 can be bonded to one another by any suitable material or method, such as by an adhesive, by brazing, by welding, by heating, by melting or by any other appropriate bonding material or process. In some examples, the first structural layer 946 is bonded directly to the core layer 944.

As described herein, in some examples, the core layer 944 can include an aperture, opening, or other space in which a functional component 952 can be disposed. In some examples, the functional component 952 can be at least partially surrounded by the core layer 944, for example, the core layer 944 can surround a periphery of the functional component 952. In some examples, the functional component 952 can include magnetic material or can be a magnet. In some examples, the functional component 952 can be a bonded magnet. That is, the functional component 952 can be a magnet that includes a magnetic material, such as magnetic powder, bonded together by a binder, for example an epoxy or resin binder. In some examples, the magnetic material can include neodymium alloy, strontium alloy, or samarium—cobalt alloy material. In some examples, the functional component 952 can be any of the functional components described herein. The functional component 952 can be bonded to the first structural layer 946 by any suitable material or process, such as by an adhesive, by brazing, by welding, by heating, by melting, or by any other appropriate bonding process or material. In some examples, the functional component 952 and the core layer 944 can have a substantially similar thickness.

In other examples, the backplate 940 can include a second structural layer 942 overlying and/or bonded to the core layer 944 and the functional component 952. In this example, the second structural layer 942 can be substantially similar to, or the same as, the first structural layer 946, without an exterior layer or coating. For example, the second structural layer 942 can include a fiber reinforced composite material, such as a fiber reinforced polymer material, fiberglass material, carbon fiber material, fiberglass-carbon fiber hybrid material, or any other appropriate fiber reinforced composite material. Further, in some examples, the second structural layer 942 can be bonded to the core layer 944 and/or the functional component 952 in a similar manner to the first structural layer 946.

FIG. 10 illustrates a cross section of a portion of a backplate 1040 of a housing of an electronic device, for example electronic devices 100, 200, 300, 400, 500, and/or 600, as described herein. The backplate 1040 can be substantially similar in construction to the backplate 940 illustrated in FIG. 9. In some examples, the backplate 1040 can include a first structural layer 1046 that can include a fiber reinforced composite material, such as a fiber reinforced polymer material, fiberglass material, carbon fiber material, fiberglass-carbon fiber hybrid material, or another appropriate fiber reinforced composite material. The backplate 1040 can further include a core layer 1044 and a functional component 1052, that are bonded to the first structural layer 1042 substantially similar to core layer 1044 and functional component 1052, as well as a second structural layer 1048 bonded to and overlying the core layer 1044 and the functional component 1052 that is substantially similar to the first structural layer 1046.

The backplate 1040 can include an exterior coating 1042, which is bonded to the first structural layer 1044. In this case, where the first structural layer is a fiber reinforced polymer material, such as fiber glass, carbon fiber, or a fiberglass-carbon fiber hybrid, the exterior coating 1042 can be a ceramic-like paint material. In some examples, the exterior layer or coating 1042 can have a thickness of less than about 1 mm, less than about 0.5 mm, less than about 0.25 mm, less than about 0.1 mm, less than about 0.075 mm, less than about 0.05 mm or even thinner.

FIG. 11 illustrates a cross section of a portion of a backplate 1140 of a housing of an electronic device, for example electronic devices 100, 200, 300, 400, 500, and/or 600, as described herein. The backplate 1140 can be substantially similar in construction to the backplate 1040 illustrated in FIG. 10. In some examples, the backplate 1140 can include a first structural layer 1146 that can include a fiber reinforced composite material, such as a fiber reinforced polymer material, fiberglass material, carbon fiber material, fiberglass-carbon fiber hybrid material, or another appropriate fiber reinforced composite material. The backplate 1140 can further include a core layer 1144 and functional component 1152 that are bonded to the first structural layer 1146 substantially similar to core layer 1044 and functional component 1052, as well as a second structural layer 1148 bonded to and overlying the core layer 1144 and the functional component 1152, that is substantially similar to the first structural layer 1146.

The backplate 1140 can include an exterior coating 1142 that is bonded to the first structural layer 1144. In this case, the exterior coating 1142 can be an in-mold coating. In some examples, the exterior layer or coating 1142 can have a thickness of less than about 1 mm, less than about 0.5 mm, less than about 0.25 mm, less than about 0.1 mm, less than about 0.075 mm, less than about 0.05 mm, less than about 0.04 mm, 0.03 mm, 0.02 mm, or even thinner.

Any of the features or aspects of the composite components discussed herein can be combined or included in any varied combination. For example, the design and shape of a composite enclosure or portion thereof is not limited in any way, and can be formed by any number of processes and can include any number of layers. Further, the layers and components of a composite enclosure can be joined or bonded by any known method, even during formation of one or more of the layers or components. The functional components described herein are merely exemplary, and do not limit in any way the number or types of functional components that can be embedded, incorporated, or otherwise included in a composite component as discussed herein. A functional composite component, as discussed herein, can form all or a portion of a component for an electronic device, such as a housing or enclosure for an electronic device. The composite construction discussed herein can also be used to form any number of additional components of an electronic device, including internal components, external components, examples, surfaces, or partial surfaces.

Although the electronic devices described herein have been illustrated and described has having certain shapes or configurations, it is expressly contemplated that the disclosure can apply to any number of desired device designs, configurations, orientations, shapes, or types. For example, the disclosure can apply to electronic devices including a housing that has rounded corners, edges, or other portions. In some examples, the disclosure can apply to an electronic device including a display that has a curved or rounded periphery or edges. In some examples, the disclosure can apply to any display and or housing geometry of an electronic device.

As used herein, the terms exterior, outer, interior, and inner are used for reference purposes only. An exterior or outer portion of a composite component can form one or more portions of an exterior surface of the component, without necessarily forming the entire exterior of outer surface thereof. Similarly, the interior or inner portion of a composite component can form or define an interior or inner portion of the component, but can also form or define a portion of an exterior or outer surface of the component.

Various inventions have been described herein with reference to certain specific embodiments and examples. However, they will be recognized by those skilled in the art that many variations are possible without departing from the scope and spirit of the inventions disclosed herein, in that those inventions set forth in the claims below are intended to cover all variations and modifications of the inventions disclosed without departing from the spirit of the inventions. The terms “including:” and “having” come as used in the specification and claims shall have the same meaning as the term “comprising.”

As described above, one aspect of the present technology can be the gathering and use of data available from various sources while operating an electronic device. The present disclosure contemplates that in some instances, this gathered data may include personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. The present technology can be configured to allow users to select to “opt in” or “opt out” of participation in the collection of personal information data during registration for services or anytime thereafter. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not target to be exhaustive or to limit the embodiments to the precise forms disclosed. It will be apparent to one of ordinary skill in the art that many modifications and variations are possible in view of the above teachings.

What is claimed is:

1. An electronic device, comprising:
a display;
a housing at least partially defining an interior volume of the electronic device, the housing retaining the display, the housing including a backplate, comprising:
an exterior layer at least partially defining an exterior surface of the housing;
a first structural layer bonded to the exterior layer;
a functional component directly bonded to the first structural layer; and
a second structural layer overlying the functional component.

2. The electronic device of claim 1, wherein the backplate further comprises a core layer at least partially surrounding the functional component, the core layer disposed between and bonded to the first structural layer and the second structural layer.

3. The electronic device of claim 1, wherein the exterior layer comprises at least one of a physical vapor deposited layer, a metal layer, a ceramic layer, a glass layer, an in-mold coated layer, an ink layer, or a paint layer.

4. The electronic device of claim 1, wherein the first structural layer and the second structural layer comprise fiberglass, carbon fiber, or a carbon fiber and fiber glass hybrid.

5. The electronic device of claim 2, wherein the core layer comprises fiberglass, carbon fiber, or a carbon fiber and fiber glass hybrid.

6. The electronic device of claim 1, wherein the functional component is less than about 0.2 mm from the exterior surface.

7. The electronic device of claim 1, wherein the functional component comprises at least one of a magnet, an antenna, a via, a cable, a battery, or a thermal spreader.

8. A housing of an electronic device, comprising:
a support layer defining an aperture;
an exterior layer bonded to the support layer and occluding the aperture, the exterior layer at least partially defining an exterior surface of the electronic device; and
a functional component bonded directly to the exterior layer through the aperture.

9. The housing of claim 8, further comprising an interior layer overlying the functional component and the support layer, the interior layer being bonded to the support layer.

10. The housing of claim 8, wherein:
the support layer at least partially defines an internal volume of the electronic device; and
at least a portion of the functional component is disposed within the interior volume.

11. The housing of claim 8, wherein the functional component comprises at least one of a magnet, an antenna, a via, a cable, a battery, or a thermal spreader.

12. The housing of claim 8, wherein the exterior layer comprises at least one of a physical vapor deposited layer, a metal layer, a ceramic layer, a glass layer, an in-mold coated layer, an ink layer, or a paint layer.

13. The housing of claim 8, wherein the exterior layer has a thickness of less than about 0.2 mm.

14. The housing of claim 8, wherein the support layer comprises one of a fiberglass, a carbon fiber, a carbon fiber and fiber glass hybrid, or steel.

15. The housing of claim 8, further comprising an adhesive layer bonding the functional component to the exterior layer.

16. The housing of claim 8, further comprising:
a second functional component;
wherein the support layer further defines a second aperture; and
wherein the second functional component is bonded directly to the exterior layer via the second aperture.

17. A housing of an electronic device, comprising:
a core layer at least partially surrounding a functional component;
a structural layer bonded to the core layer and at least partially covering the functional component; and
an exterior layer bonded to the structural layer and defining an exterior surface of the electronic device.

18. The housing of claim 17, wherein the functional component is disposed less than about 0.2 mm from the exterior surface.

19. The housing of claim 17, wherein the structural layer comprises at least one of steel, titanium, or aluminum.

20. The housing of claim 17, further comprising:
an interior structural layer bonded to a surface of the core layer opposite the structural layer;
wherein the structural layer, the core layer, and the interior structural layer cooperate to substantially surround the functional component.
